(19) United States
(12) Patent Application Publication
(10) Pub. No.: US 2026/0190740 A1
(43) Pub. Date: Jul. 2, 2026

(54) Double-Sided Display Device

(71) Applicant: LG Display Co., Ltd., Seoul (KR)

(72) Inventors: JiHun Song, Paju-si (KR); Choonghyo Kim, Paju-si (KR)

(21) Appl. No.: 19/424,591

(22) Filed: Dec. 18, 2025

(30) Foreign Application Priority Data
Dec. 30, 2024 (KR) 10-2024-0200564

(51) Int. Cl. H10K 59/38; H10K 59/131

(52) U.S. Cl. CPC H10K 59/38; H10K 59/131

(57) ABSTRACT

The present disclosure provides a double-sided display device in which the first display unit comprises the first pixel area, the first filter area, and the first transmissive area, and the second display unit comprises the second pixel area, the second filter area, and the second transmissive area, and in which the first pixel area overlaps with the second filter area, the first filter area overlaps with the second pixel area, and the first transmissive area overlaps with the second transmissive area.

### CROSS-REFERENCE TO RELATED APPLICATIONS

This application claims priority under 35 U.S.C. § 119(a) to the Republic of Korea Patent Application No. 10-2024-0200564, filed on Dec. 30, 2024, the entire contents of which are hereby expressly incorporated by reference into the present application.

### TECHNICAL FIELD

The present disclosure relates to a double-sided apparatus and particularly to, for example, without limitation, a double-sided display device.

### BACKGROUND

As an information society develops, a demand for a display device for displaying an image is increasing in various forms. Accordingly, various display devices such as a liquid crystal display (LCD), a plasma display panel (PDP), and an organic light emitting display (OLED) have recently been used.

Among the display devices, the organic light emitting display device is a self-luminous type, has better viewing angle and contrast ratio than the liquid crystal display (LCD), and has an advantage of being lightweight and thin because a separate backlight is not required and power consumption is advantageous. In addition, the organic light emitting display device has an advantage of being driven with a low DC voltage, having a fast response speed, and especially low manufacturing cost.

In addition, by providing a transmissive area in some areas of such an organic light emitting display device, a transparent display device that can see an object on a rear surface of the organic light emitting display device when an image is not displayed is also utilized. Recently, research on a double-sided display device using a transparent display device is being conducted.

### SUMMARY

The present disclosure has been made in view of the above problems and other limitations associated with the related art.

Accordingly, it is an aspect of the present disclosure to provide a double-sided display with transmissive area.

In accordance with an aspect of the present disclosure, the above and other technical effects can be accomplished by the provision of a double-sided display device comprising a first display unit and a second display unit on the first display unit, wherein the first display unit includes a first pixel area, a first filter area, and a first transmissive area, and the second display unit includes a second pixel area, a second filter area, and a second transmissive area, wherein each of the first pixel area and the second pixel area includes a light emitting layer, and each of the first filter area and the second filter area includes a color filter, and wherein the first pixel area overlaps the second filter area, the first filter area overlaps the second pixel area, and the first transmissive area overlaps the second transmissive area

It is to be understood that both the foregoing general description and the following detailed description are examples and explanatory and are intended to provide further explanation of the inventive concepts as claimed

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description explain the principle of the disclosure. In the drawings:

FIG. 1 is a block diagram of a double-sided display device according to an embodiment of the present disclosure.

FIG. 2 is a plan view of a double-sided display device according to one or more embodiments of the present disclosure.

FIG. 3 is a plan view of a double-sided display device according to one or more embodiments of the present disclosure.

FIG. 4 is a circuit diagram of a double-sided display device according to an embodiment of the present disclosure.

FIG. 5 is a cross-sectional view of a double-sided display device according to an embodiment of the present disclosure, which is a cross-sectional view taken along line A-A′ of FIGS. 2 and 3.

FIG. 6 is a cross-sectional view of a double-sided display device according to an embodiment of the present disclosure, which is a cross-sectional view taken along area B of FIGS. 2 and 3.

FIG. 7 is a cross-sectional view of a double-sided display device according to another embodiment of the present disclosure, which is a cross-sectional view taken along line A-A′ of FIGS. 2 and 3.

FIG. 8 is a cross-sectional view of a double-sided display device according to another embodiment of the present disclosure, which is a cross-sectional view taken along area B of FIGS. 2 and 3

FIG. 9 is a plan view of a double-sided display device according to an embodiment.

FIG. 10 is a plan view of a double-sided display device according to another embodiment.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

Advantages and features of the present disclosure, and implementation methods thereof, will be clarified through the following examples described with reference to the accompanying drawings. The present disclosure may, however, be embodied in different forms and should not be construed as limited to the examples set forth herein. Rather, these examples are provided so that the specification of the present disclosure will be thorough, complete, and fully convey the scope of the present disclosure to those skilled in the art.

A shape, a size, a ratio, an angle, and a number disclosed in the accompanying drawings for describing the examples of the present disclosure are merely illustrative and, thus, the present disclosure is not limited to the illustrated details. Unless stated otherwise, the like reference numerals refer to like elements throughout the specification. In the following description, when the detailed description of the relevant known function or configuration is determined to unnecessarily obscure an important point of the present disclosure, the detailed description will be omitted. In a case where terms such as ‘comprise’, ‘have’, and ‘include’ described in the present disclosure are used, another portion can be added unless ‘only’ is used. The terms of a singular form can include plural forms unless referred to the contrary.

In interpreting the components, it is interpreted as including an error range even if there is no separate explicit description of an error range.

In describing a position relationship, for example, when the position relationship is described using terms such as ‘upon’, ‘above’, ‘below’ and ‘next to’, one or more portions can be disposed between two other portions unless ‘just’ or ‘direct’ is used. The terms, such as “below,” “lower,” “above,” “upper”, and the like, can be used herein to describe a relationship between elements as illustrated in the drawings. It will be understood that the terms are spatially relative and based on the orientation depicted in the drawings.

A description of a time relationship can include a case in which the temporal precedence relationship is described as “after”, “following”, or “before”, etc., and is not continuous unless “right away” or “directly”, is used.

Although the terms such as first, second, and the like are used to describe various components, these components are not limited by these terms. These terms are used only to distinguish one component from another. Therefore, a first component mentioned below can be a second component within a technical idea of a present disclosure.

It will be understood that, although the terms such as “first,” “second,” “A,” “B,” “(a),” and “(b)”, etc., can be used herein to describe various elements, these elements should not be limited by these terms. These terms are only used to distinguish one element from another. For example, a first element could be termed a second element, and, similarly, a second element could be termed a first element, without departing from the scope of the present disclosure. Further, the term “can” fully encompasses all the meanings and coverages of the term “may” and vice versa.

Features of each of the various examples of the present disclosure can be partially or entirely coupled or combined with each other, technically various interworking and driving are possible, and each of the examples can be independently implemented with respect to each other or can be implemented together in a related relationship.

Hereinafter, embodiments of the present disclosure will be described in detail with reference to the accompanying drawings. All the components of each display device/apparatus according to all embodiments of the present disclosure are operatively coupled and configured.

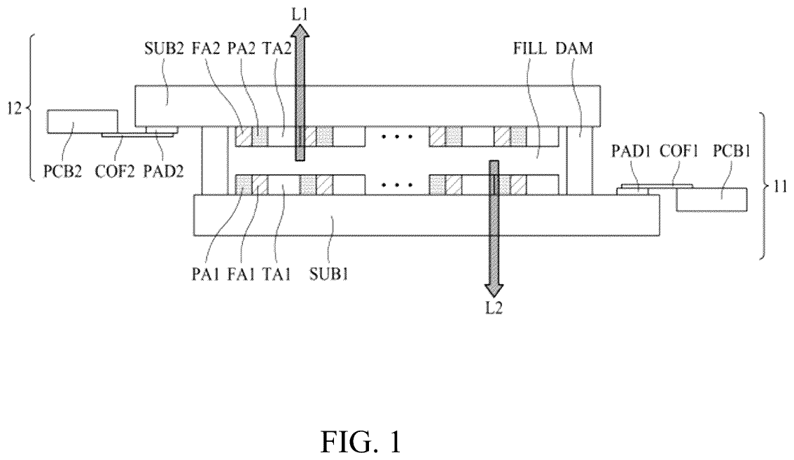

FIG. 1 is a block diagram of a double-sided display device 10 according to an embodiment of the present disclosure.

Referring to FIG. 1, the double-sided display device 10 according to an embodiment of the present disclosure may include a first display unit 11 and a second display unit 12 disposed on the first display unit 11. The first display unit 11 and the second display unit 12 may be bonded to each other through a filler FILL and a dam DAM. The dam DAM may be disposed at an edge of the first display unit 11 and the second display unit 12 and may maintain an interval between the first display unit 11 and the second display unit 12. In addition, the filler FILL may fill a space between the first display unit 11 and the second display unit 12 and seal the first display unit 11 and the second display unit 12.

The first display unit 11 may include a plurality of first pixel areas PA1, a plurality of first filter areas FA1, and a plurality of first transmissive areas TA1 disposed on a first substrate SUB1. In addition, the second display unit 2 may include a plurality of second pixel areas PA2, a plurality of second filter areas FA2, and a plurality of second transmissive areas TA2 disposed under a second substrate SUB2.

The first pixel area PA1 may overlap the second filter area FA2, the first filter area FA1 may overlap the second pixel area PA2, and the first transmissive area TA1 may overlap the second transmissive area TA2. For example, referring to FIG. 1, the first pixel area PA1, the first filter area FA1, and the first transmissive area TA1 may be sequentially disposed in the first display unit 11. In this case, the second filter area FA2, the second pixel area PA2, and the second transmissive area TA2 may be sequentially disposed in the second display unit 12.

The first pixel area PA1 includes a light emitting device and may generate a first light L1 directed upward of the double-sided display device 10. The second pixel area PA2 includes a light emitting device and may generate a second light L2 directed downward of the double-sided display device 10.

The first filter area FA1 and the second filter area FA2 include a color filter and may transmit light in a specific wavelength band. The first light L1 generated in the first pixel area PA1 may transmit the second filter area FA2, and the second light L2 generated in the second pixel area PA2 may transmit the first filter area FA1. That is, the first display unit 11 may emit light toward the second display unit 12, and the second display unit 12 may emit light toward the first display unit 11. Accordingly, the present disclosure may disclose the double-sided display device 10 emitting light in both upward and downward directions.

The first transmissive area TA1 and the second transmissive area TA may be areas through which external light is transmitted. Accordingly, through the first transmissive area TA1 and the second transmissive area TA, the user can visually recognize objects disposed at upper and lower portions of the display device.

In conclusion, the present disclosure may disclose the double-sided display device 10 capable of displaying an image in both directions while having a transmissive area.

A first pad portion PAD may be disposed at an edge of the first display unit 11. The first pad portion PAD may transfer various signals received from a first flexible circuit board COF1 and a first printed circuit board PCB1 to the first pixel area PA1. Accordingly, the light emitting device disposed in the first pixel area PA1 may be driven.

Similarly, a second pad portion PAD may be disposed at an edge of the second display unit 12. The second pad portion PAD may transfer various signals received from a second flexible circuit board COF2 and a second printed circuit board PCB2 to the second pixel area PA2. Accordingly, the light emitting device disposed in the second pixel area PA2 may be driven.

Since the first display unit 11 and the second display unit 12 are connected to different flexible circuit boards COF1 and COF2, and are connected to different printed circuit boards PCB1 and PCB2, the first display unit 11 and the second display unit 12 may display different images. In addition, the first display unit 11 and the second display unit 12 may display the same image.

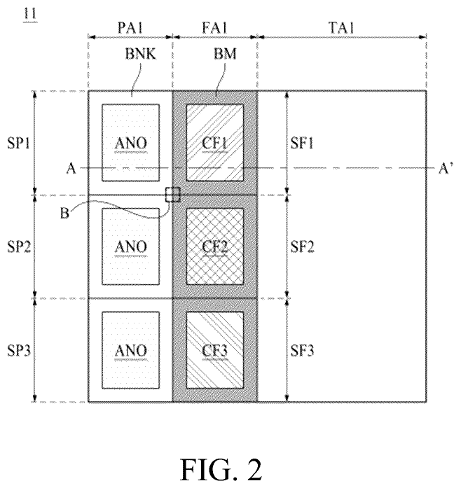

FIG. 2 is a plan view of a double-sided display device 10 according to an embodiment of the present disclosure. Specifically, FIG. 2 illustrates a plan view of the first display unit 11.

Referring to FIG. 2, the first display unit 11 may include a first pixel area PA1, a first filter area FA1, and a first transmissive area TA1. The first pixel area PA1, the first filter area FA1, and the first transmissive area TA1 may be disposed sequentially along a row direction.

The first pixel area PA1 may include a plurality of sub-pixels SP. The plurality of sub-pixels SP may include a first sub-pixel SP1, a second sub-pixel SP2, and a third sub-pixel SP3. The first sub-pixel SP1, the second sub-pixel SP2, and the third sub-pixel SP3 may be sequentially disposed along a column direction. Each of the first sub-pixel SP1, the second sub-pixel SP2, and the third sub-pixel SP3 may include a first electrode ANO and a bank BNK surrounding the first electrode ANO.

The first sub-filter area FA1 may include a plurality of sub-filter areas SF1. The plurality of sub-filter areas SF1 may include a first sub-filter area SF2, a second sub-filter area SF2, and a third sub-filter area SF3. The first sub-filter area SF1, the second sub-filter area SF2, and the third sub-filter area SF3 may be sequentially disposed along the column direction. Each of the first sub-filter area SF1, the second sub-filter area SF2, and the third sub-filter area SF3 may include a color filter CF and a black matrix BM surrounding the color filter CF.

The color filter CF may include a first color filter CF1 disposed in the first sub-filter area SF1, a second color filter CF2 disposed in the second sub-filter area SF2, and a third color filter CF3 disposed in the third sub-filter area SF3. The first color filter CF1 may transmit only red light, the second color filter CF2 may transmit only green light, and the third sub-filter region SF3 may transmit only blue light, but the present disclosure is not limited thereto.

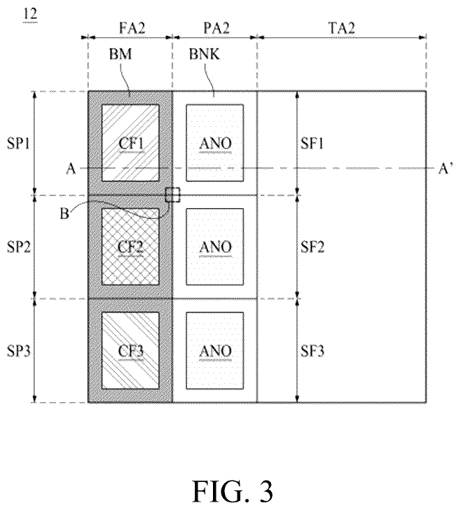

FIG. 3 is a plan view of a double-sided display device 10 according to an embodiment of the present disclosure. Specifically, FIG. 3 illustrates a plan view of the second display unit 12.

Referring to FIG. 3, the second display unit 12 may include a second filter area FA2, a second pixel area PA2, and a second transmissive area TA2. The second filter area FA2, the second pixel area PA2, and the second transmissive area TA2 may be disposed sequentially along the row direction.

Like the first filter area FA1, the second filter area FA2 may include a first sub-filter area SF1, a second sub-filter area SF2, and a third sub-filter area SF3. The first sub-filter area SF1 of the second filter area FA2 corresponds to the first sub-pixel SP1 of the first pixel area PA1, and the second sub-filter area SF2 of the second filter area FA2 corresponds to the second sub-pixel SP2 of the first pixel area PA1, and the third sub-filter area SF3 of the second filter area FA2 may correspond to the third sub-pixel SP3 of the first pixel area PA1.

Like the first pixel area PA1, the second pixel area PA2 may include a first sub-pixel SP1, a second sub-pixel SP2, and a third sub-pixel SP3. The first sub-pixel SP1 of the second pixel area PA2 corresponds to the first sub-filter area SF1 of the first filter area FA1, and the second sub-pixel SP2 of the second pixel area PA2 corresponds to the second sub-filter area SF2 of the first filter area FA1, and the third sub-pixel SP3 of the second pixel area PA2 may correspond to the third sub-filter area SF3 of the first filter area FA1.

That is, each of the sub-filters SF of the second filter area FA2 may correspond to each of the sub-pixels SP of the first pixel area PA1. In addition, each of the sub-pixels SP of the second pixel area PA2 may correspond to each of the sub-filters SF of the first filter area FA1.

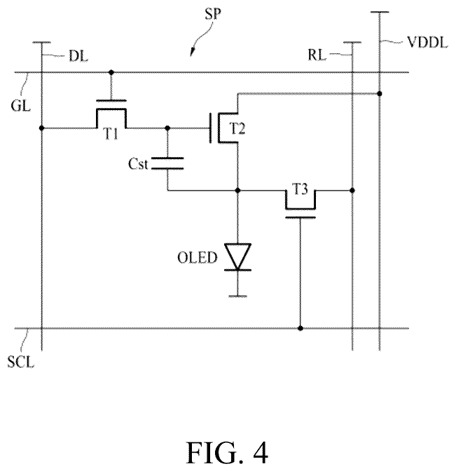

FIG. 4 is a circuit diagram of a double-sided display device 10 according to an embodiment of the present disclosure. In detail, a circuit configuration of any one sub-pixel SP is shown.

Referring to FIG. 4, a double-sided display device 10 according to an embodiment of the present disclosure may include a gate line GL, a data line DL, a high power line VDDL, a reference line RL, a sensing control line SCL, a switching thin film transistor T1, a driving thin film transistor T2, a sensing thin film transistor T3, a capacitor Cst, and a light emitting device OLED.

The gate line GL may supply a gate signal to a gate electrode of the switching thin film transistor T1. The data line DL may supply a data signal to a source electrode of the switching thin film transistor T1. The high power line VDDL may supply a high power to a drain electrode of the driving thin film transistor T2. The reference line RL may be connected to a drain electrode of the sensing thin film transistor T3.

The sensing control line SCL may supply a sensing control signal to a gate electrode of the sensing thin film transistor T3. In addition, the sensing control line SCL may be omitted. In this case, the gate electrode of the sensing thin film transistor T3 may be connected to the gate line GL to receive a sensing control signal from the gate line GL.

The switching thin film transistor T1 may be switched according to a gate signal supplied to the gate line GL to supply a data voltage supplied from the data line DL to the driving thin film transistor T2.

The driving thin film transistor T2 may be switched according to the data voltage supplied from the switching thin film transistor T1 to generate a data current from a high power source supplied from the high power source line VDDL and supply it to the light emitting device OLED.

The sensing thin film transistor T3 may supply a voltage of the driving thin film transistor T2 to the reference line RL in response to the sensing control signal supplied from the sensing control line SCL. In addition, in a sensing mode, the sensing thin film transistor T3 may sense a threshold voltage deviation of the driving thin film transistor T2, which is a cause of image quality deterioration.

The capacitor Cst may maintain a data voltage supplied to the driving thin film transistor T2 during one frame. The capacitor Cst may be connected to a gate electrode and a source electrode of the driving thin film transistor T2, respectively.

The light emitting device OLED may emit light according to the data current supplied from the driving thin film transistor T2. The light emitting device OLED may include a first electrode, a second electrode, and a light emitting layer disposed between the first electrode and the second electrode. The first electrode of the light emitting device OLED may be connected to a source electrode of the driving thin film transistor T2, and the second electrode of the light emitting device OLED may be connected to the low power line. Although not shown in FIG. 1, a low power line for supplying low power may be additionally provided to the second electrode of the light emitting device OLED. In addition, in the present disclosure, the power line may mean at least one of a high power line and a low power line.

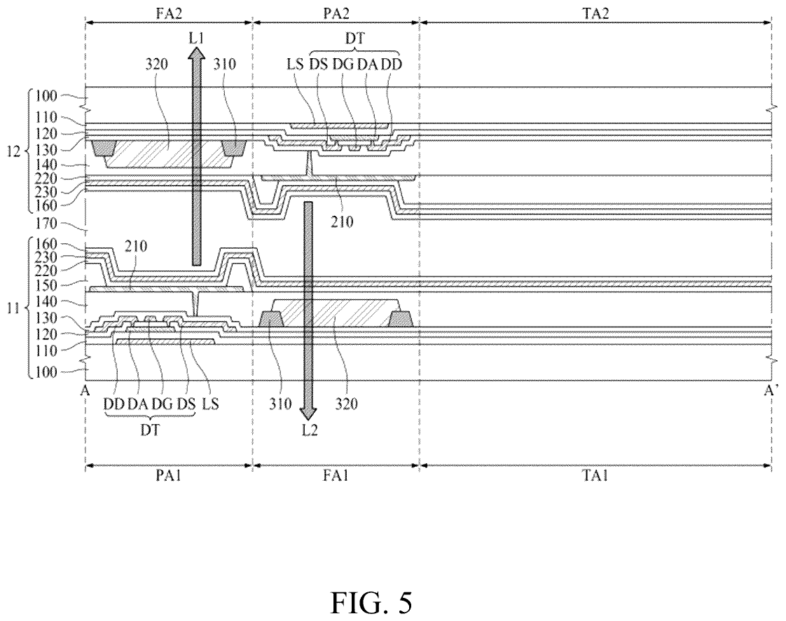

FIG. 5 is a cross-sectional view of a double-sided display device 10 according to an embodiment of the present disclosure, which is taken along line A-A′ of FIGS. 2 and 3. Specifically, FIG. 5 illustrates the first pixel area PA1, the first filter area FA1, and the first transmissive area TA1 of the first display unit 11, and the second filter area FA2, the second pixel area PA2, and the second transmissive area TA2 of the second display unit 12.

Referring to FIG. 5, the first display unit 11 and the second display unit 12 may be bonded through a filler 170.

In the first display unit 11, a substrate 100 may include a first pixel area PA1, a first filter area FA1, and a first transmissive area TA1.

The substrate 100 may be made of glass or plastic, but is not limited thereto. Since the display device according to an embodiment of the present disclosure is a double-sided display device, the substrate 100 may be formed of a transparent material.

A light shielding layer LS may be disposed on the substrate 100. In addition, the light shielding layer LS may be disposed in the first pixel area PA1.

A first insulating layer 110 may be disposed on the light shielding layer LS. In addition the first insulating layer 110 may be disposed in the first pixel area PA1, the first filter area FA1, and the first transmissive area TA1. The first insulating layer 110 may be formed of an inorganic insulating material.

The driving transistor DT may be disposed on the first insulating layer 110. The driving transistor DT may include an active layer DA, a gate electrode DG, a source electrode DS, and a drain electrode DD.

The active layer DA may be disposed on the first insulating layer 110. The active layer DA may be disposed in the first pixel area PA1. At least a portion of the active layer DA may overlap the light shielding layer LS. Accordingly, light incident from a lower portion of the substrate 100 may be blocked by the light shielding layer LS and may be prevented from being incident on at least a partial area of the active layer DA.

A second insulating layer 120 may be disposed on the active layer DA. The second insulating layer 120 may be disposed in the first pixel area PA1, the first filter area FA1, and the first transmission area TA1. The second insulating layer 120 may be disposed on an entire surface of the substrate 100 except for a contact hole area. The second insulating layer 120 may be formed of an inorganic insulating material.

The gate electrode DG, the source electrode DS, and the drain electrode DD may be disposed on the second insulating layer 120. The gate electrode DG, the source electrode DS, and the drain electrode DD may be disposed in the first pixel area PA1. In addition, the gate electrode DG, the source electrode DS, and the drain electrode DD may be spaced apart from each other.

The source electrode DS may overlap the active layer DA. In addition, the source electrode DS may be connected to one end region of the active layer DA through a contact hole disposed in the second insulating layer 120.

The gate electrode DG may be disposed between the drain electrode DD and the source electrode DS while overlapping the active layer DA.

The drain electrode DD may overlap the active layer DA. In addition, the drain electrode DD may be connected to the other end region of the active layer DA through a contact hole disposed in the second insulating layer 120. The gate electrode DG, the source electrode DS, and the drain electrode DD may be formed of the same material through the same process in the same layer.

A third insulating layer 130 may be disposed on the gate electrode DG, the source electrode DS, and the drain electrode DD. The third insulating layer 130 may be disposed in the first pixel area PA1, the first filter area FA1, and the first transmission area TA1. The third insulating layer 130 may be disposed on the entire surface of the substrate 100 except for the contact hole area. The third insulating layer 130 may be formed of an inorganic insulating material.

The fourth insulating layer 140 may be disposed on the third insulating layer 130. The fourth insulating layer 140 may be disposed in the first pixel area PA1, the first filter area FA1, and the first transmissive area TA1. In addition, the fourth insulating layer 140 may include a planarization layer made of an organic insulation material. The fourth insulating layer 140 may include a plurality of insulating layers. For example, the fourth insulating layer 140 may have a two-layered structure of a passivation layer made of an inorganic material and a planarization layer made of an organic material.

A bank 150 and a light emitting device 200 may be disposed on the fourth insulating layer 140. The bank 150 and the light emitting device 200 may be disposed in the first pixel area PA1. In addition, the light emitting device 200 may include a first electrode 210, a light emitting layer 220 and a second electrode 230.

The first electrode 210 may be disposed on the fourth insulating layer 140. The first electrode 210 may function as an anode. The first electrode 210 may be connected to the source electrode DS through the contact hole, but is not limited thereto. For example, the first electrode 210 may be connected to the drain electrode DD

The bank 150 may be disposed on the fourth insulating layer 140. In addition, the bank 150 may cover both ends of the first electrode 210. A partial area of the first electrode 210 exposed by the bank 150 may be a light emitting area. The bank 150 may be disposed in a boundary area between the first pixel area PA and the first filter area FA1. In addition, the bank 150 may be disposed in a boundary area between the first pixel area PA and the first transmissive area TA1.

The light emitting layer 220 may be disposed on the first electrode 210 and the bank 150. The light emitting layer 220 may be disposed continuously between the plurality of sub-pixels. In this case, the light emitting layer 220 may emit white light. Alternatively, the light emitting layer 220 may include a blue light emitting layer, a green light emitting layer, and a red light emitting layer patterned for each of the plurality of sub-pixels. The light emitting layer 220 may generate the first light L1 directed to an upper portion of the double-sided display device 10.

The second electrode 230 may be disposed on the light emitting layer 220. The second electrode 230 may function as a cathode. In addition, the second electrode 230 may be disposed entirely on the plurality of sub-pixels and the boundary therebetween.

Since the first display unit 11 is made of a top emission type, the second electrode 230 may include a transparent conductive material such as an indium tin oxide (ITO) or an indium zinc oxide (IZO) to transmit light generated in the light emitting layer 220 upward.

A protective layer 160 is disposed on the light emitting device 200 and may protect the light emitting device 200. The protective layer 160 may be disposed in the first pixel area PA1, the first filter area FA1, and the first transmissive area TA1. In addition, the protective layer 160 may be formed of an inorganic insulating material.

A black matrix 310 and a color filter 320 may be disposed in the first filter area FA1. The black matrix 310 and the color filter 320 may be disposed on a third insulating layer 130. The fourth insulating layer 140 may cover the black matrix 310 and the color filter 320 and may planarize upper portions of the black matrix 310 and the color filter 320.

The black matrix 310 may be disposed in an area adjacent to the bank 150, but is not limited thereto. In addition, in the first filter area FA1, the color filter 320 may be disposed on an upper surface of the third insulating layer 130 exposed by the black matrix 310. The color filter 320 may transmit only light of a specific wavelength band. For example, the color filter 320 may transmit only any one of red, green, and blue light.

Meanwhile, since the first transmissive area TA1 does not include a metal layer, external light may be transmitted therethrough. Accordingly, the user can see an object disposed under the display device through the first transmissive area TA1.

Like the first display unit 11, the second display unit 12 may include a second filter area FA2, a second pixel area PA2, and a second transmissive area TA2.

The second filter area FA2 may overlap with the first pixel area PA1. Like the first filter area FA1, the second filter area FA2 may include a black matrix 310 and a color filter 320. Accordingly, the first light L1 generated in the light emitting layer 220 of the first pixel area PA1 may pass through the color filter 320 of the second filter area FA2. Accordingly, the sub-pixels of the first pixel area PA1 may emit light.

The second pixel area PA2 may overlap with the first filter area FA1. Like the first pixel area PA1, the second pixel area PA2 may include the driving transistor DT and the light emitting device 200. The light emitting layer 220 of the second pixel area PA2 may generate a second light L2 directed to a lower portion of the double-sided display device 10. Accordingly, the second light L2 generated in the light emitting layer 220 of the second pixel area PA2 may pass through the color filter 320 of the first filter area FA1. Accordingly, the sub-pixels of the second pixel area PA2 may emit light.

The second transmissive area TA2 may overlap with the first transmissive area TA1. Like the first transmissive area TA1, since the second transmissive area TA2 does not include a metal layer, external light may be transmitted therethrough. Accordingly, the user can visually recognize an object disposed on the upper portion of the display device through the second transmissive area TA2. In conclusion, the user can visually recognize an object disposed in both directions of the display device through the first transmissive area TA1 and the second transmissive area TA2.

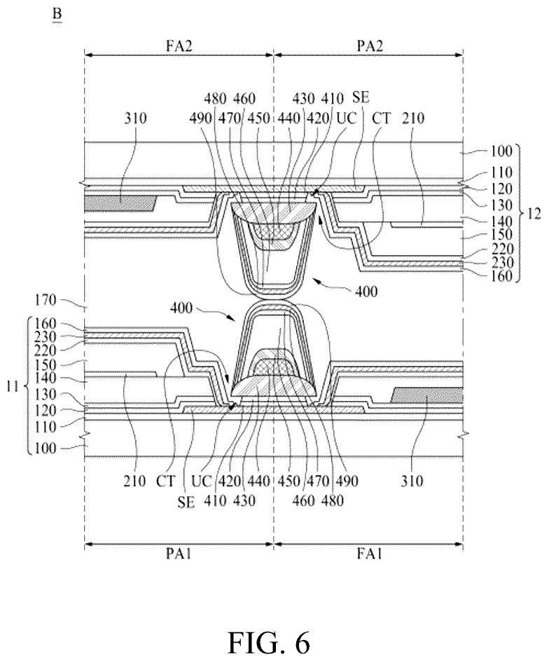

FIG. 6 is a cross-sectional view of a double-sided display device 10 according to an embodiment of the present disclosure, which is a cross-sectional view taken along a area B of FIGS. 2 and 3.

In detail, FIG. 6 illustrates an area that is a boundary area between the first pixel area PA1 and the first filter area FA1, and is not adjacent to the first electrode 210 and the color filter 320. In addition, an area that is a boundary area between the second pixel area PA2 and the second filter area FA2 and is not adjacent to the first electrode 210 and the color filter 320. That is, an area including a point where the first sub-pixel SP1, the second sub-pixel SP2, the first sub-color filter area SF1, and the second sub-color filter area SF2 meet is illustrated.

Referring to FIG. 6, in the first display unit 11, an auxiliary electrode SE may be disposed in a boundary area between the first pixel area PA1 and the first filter area FA1. The auxiliary electrode SE is electrically connected to the second electrode 230 and may reduce the resistance of the second electrode 230. Accordingly, a voltage drop caused by a resistance of the second electrode 230 may be prevented.

In the first display unit 11, the auxiliary electrode SE may be disposed on the first insulating layer 110. An upper surface of the auxiliary electrode SE may be exposed to an outside by a contact hole CT. The contact hole CT may be formed through the second insulating layer 120, the third insulating layer 130, and the fourth insulating layer 140.

A gap spacer 400 is disposed on the upper surface of the auxiliary electrode SE, and may be disposed inside the contact hole CT. That is, the gap spacer 400 may be spaced apart from a stacked structure of the first pixel area PA1 and a stacked structure of the first filter area FA1. An area in which the gap spacer 400 is in contact with the auxiliary electrode SE may be smaller than an area of an entire upper surface of the auxiliary electrode SE. That is, a portion of the upper surface of the auxiliary electrode SE may be exposed to the outside by the gap spacer 400.

The gap spacer 400 may include a first material layer 410, a second material layer 420, a third material layer 430, a fourth material layer 440, a fifth material layer 450, a sixth material layer 460, a seventh material layer 470, an eighth material layer 480, and a ninth material layer 490, which are sequentially stacked on the auxiliary electrode SE.

The first material layer 410 may include the same material as the second insulating layer 120, and the second material layer 420 may include the same material as the third insulating layer 130. That is, the first material layer 410 and the second insulating layer 120 may be formed by the same process, and the second material layer 420 and the third insulating layer 130 may be formed by the same process.

Each of the third material layer 430, the fourth material layer 440, and the fifth material layer 450 may include the same material as that of the color filter 320. For example, the third material layer 430 may include the same material as that of the first color filter CF1 in the first sub-color filter area SF1, the fourth material layer 440 may include the same material as that of the second color filter CF2 in the second sub-color filter area SF2, and the fifth material layer 450 may include the same material as that of the third color filter CF3 in the third sub-color filter area SF3, but is not limited thereto. The third material layer 430, the fourth material layer 440, and the fifth material layer 450 may be formed simultaneously in a process of forming the color filter 320.

An area of a lower surface of the third material layer 430 may be greater than an area of an upper surface of the second material layer 420. That is, an edge of the lower surface of the third material layer 430 may be exposed to the outside. Accordingly, an undercut area UC may be formed by a side surface of the first material layer 410, a side surface of the second material layer 420, and the lower surface of the third material layer 430.

The sixth material layer 460 may include the same material as the fourth insulating layer 140, the seventh material layer 470 may include the same material as the light emitting layer 220, the eighth material layer 480 may include the same material as the second electrode 230, and the ninth material layer 490 may include the same material as the protective layer 160. That is, the sixth material layer 460 and the fourth insulating layer 140 may be formed by the same process, the seventh material layer 470 and the light emitting layer 220 may be formed by the same process, the eighth material layer 480 and the second electrode 230 may be formed by the same process, and the ninth material layer 490 and the protective layer 160 may be formed by the same process.

Meanwhile, material layers on an upper portion of the third material layer 430 may not be continuously formed with the material layers of the first pixel area PA1 and the first filter area FA1 by the undercut area UC. Specifically, since the light emitting layer 220 and the seventh material layer 470 are formed of the same material, they may be formed through the same process. In this case, the light emitting layer 220 and the seventh material layer 470 may not be continuously formed by the undercut area UC and may be spaced apart from each other in an area overlapping with the contact hole CT.

Likewise, the second electrode 230 and the eighth material layer 480 may not be continuously formed by the undercut area UC and may be spaced apart from each other in an area overlapping with the contact hole CT. Accordingly, the second electrode 230 is in contact with the auxiliary electrode SE, and the second electrode 230 and the auxiliary electrode SE may be electrically connected to each other.

Likewise, the protective layer 160 and the ninth material layer 490 may not be continuously formed by the undercut area UC and may be spaced apart from each other in an area overlapping with the contact hole CT. Accordingly, the protective layer 160 may cover an end of the second electrode 230 and stably protect the second electrode 230.

Like the first display unit 11, the second display unit 12 may be disposed with an auxiliary electrode SE, a contact hole CT, and a gap spacer 400.

The gap spacer 400 of the first display unit 11 may overlap with the gap spacer 400 of the second display unit 12. In addition, an upper surface of the gap spacer 400 of the first display unit 11 may be in contact with an upper surface of the gap spacer 400 of the second display unit 12. Accordingly, a gap between the first display unit 11 and the second display unit 12 may be stably maintained.

Meanwhile, the gap spacers 400 of the first display unit 11 and the second display unit 12 are in contact with each other, and an impact may be applied to the gap spacers 400 of the first display unit 11 and the second display unit 12. In this case, cracks may occur in an uppermost layer of the gap spacers 400 of the first display unit 11 and the second display unit 12. More specifically, cracks may occur in the ninth material layer 490 of the gap spacer 400.

However, the present disclosure discloses that the gap spacer 400 is not continuously formed with a structure of the pixel area PA and the filter area FA but is spaced apart from each other. Accordingly, the impact applied to the gap spacer 400 may be prevented from affecting the pixel area PA and the filter area FA. Specifically, even if a crack occurs in the ninth material layer 490 of the gap spacer 400, the impact applied to the ninth material layer 490 may not be transferred to the protective layer 160. Accordingly, the protective layer 160 may stably protect the light emitting device 200 and prevent moisture from penetrating into the pixel area PA.

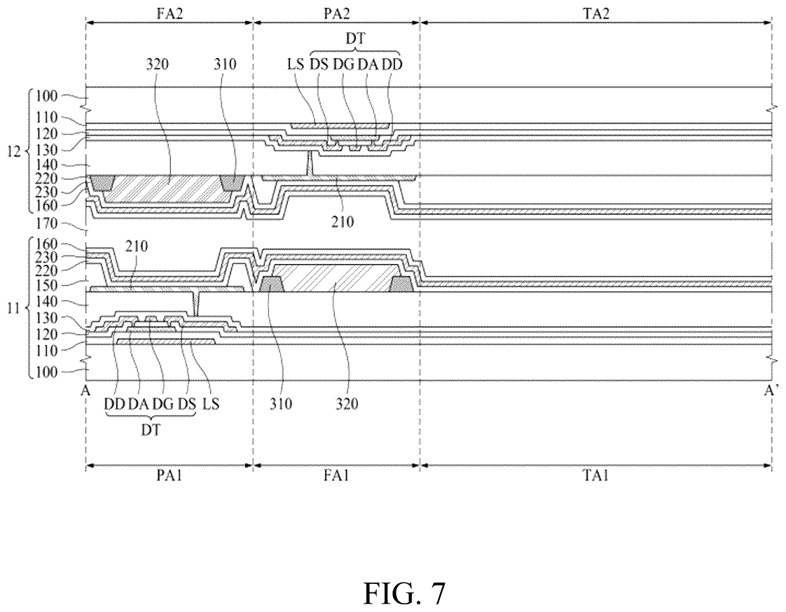

FIG. 7 is a cross-sectional view of a double-sided display device 10 according to another embodiment of the present disclosure, which is a cross-sectional view taken along line A-A′ of FIGS. 2 and 3.

FIG. 5 shows that the black matrix 310 and the color filter 320 are disposed on the upper surface of the third insulating layer 130, whereas FIG. 7 shows that the black matrix 310 and the color filter 320 are disposed on the upper surface of the fourth insulating layer 140.

Referring to FIG. 7, in the first filter area FA1 and the second filter area FA2, the black matrix 310 and the color filter 320 may be disposed on a upper surface of the fourth insulating layer 140. The black matrix 310 may be spaced apart from the bank 150, but is not limited thereto.

The light emitting layer 220, the second electrode 230, and the protective layer 160 may extend on the bank 150 and may be disposed on the black matrix 310 and the color filter 320.

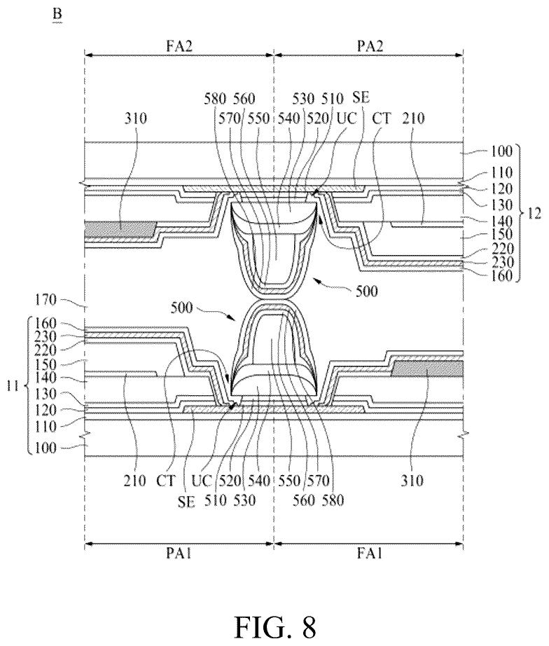

FIG. 8 is a cross-sectional view of a double-sided display device 10 according to another embodiment of the present disclosure, which is a cross-sectional view taken along the area B of FIGS. 2 and 3.

FIG. 6 discloses a gap spacer 400 using a plurality of color filters CF, while FIG. 8 discloses a gap spacer 500 without the plurality of color filters CF.

Referring to FIG. 8, the gap spacer 500 may include a first material layer 510, a second material layer 520, a third material layer 530, a fourth material layer 540, a fifth material layer 550, a sixth material layer 560, a seventh material layer 570, and an eighth material layer 580, which are sequentially stacked on the auxiliary electrode SE.

The first material layer 510 may include the same material as the second insulating layer 120, the second material layer 520 may include the same material as the third insulating layer 130, the third material layer 530 may include the same material as the fourth insulating layer 140, and the fourth material layer 540 may include the same material as the bank 150. That is, the first material layer 510 and the second insulating layer 120 may be formed by the same process, the second material layer 520 and the third insulating layer 130 may be formed by the same process, the third material layer 530 and the fourth insulating layer 140 may be formed by the same process, and the fourth material layer 540 and the bank 150 may be formed by the same process.

An area of a lower surface of the third material layer 530 may be larger than an area of an upper surface of the second material layer 520. That is, an edge of the lower surface of the third material layer 530 may be exposed to the outside. Accordingly, an undercut area UC may be formed by a side surface of the first material layer 510, a side surface of the second material layer 520, and the lower surface of the third material layer 530.

The fifth material layer 550 may be a column spacer. The fifth material layer 550 may not be formed by the same process as the material layer used in the pixel area PA and the filter area FA. That is, the fifth material layer 550 may have an independent structure only for the gap spacer 500. Accordingly, since the fifth material layer 550 is irrelevant to the pixel area PA and the filter area FA, a thickness of the fifth material layer 550 may be independently set. That is, a thickness of the gap spacer 500 may be freely adjusted through the fifth material layer 550. The fifth material layer 550 may be an organic insulating material, but is not limited thereto.

The sixth material layer 560 may include the same material as the light emitting layer 220, the seventh material layer 570 may include the same material as the second electrode 230, and the eighth material layer 580 may include the same material as the protective layer 160. That is, the sixth material layer 560 and the light emitting layer 220 may be formed by the same process, the seventh material layer 570 and the second electrode 230 may be formed by the same process, and the eighth material layer 580 and the protective layer 160 may be formed by the same process.

As described above in FIG. 6, material layers on an upper portion of the third material layer 430 may not be continuously formed. Specifically, since the light emitting layer 220 and the sixth material layer 560 are formed of the same material, they may be formed through the same process. In this case, the light emitting layer 220 and the sixth material layer 560 are not continuously formed by the undercut area UC and may be spaced apart from each other in an area overlapping with the contact hole CT.

Likewise, the second electrode 230 and the seventh material layer 570 may not be continuously formed by the undercut area UC and may be spaced apart from each other in an area overlapping with the contact hole CT. Accordingly, the second electrode 230 is in contact with the auxiliary electrode SE, and the second electrode 230 may be electrically connected to the auxiliary electrode SE.

Likewise, the protective layer 160 and the eighth material layer 580 may not be continuously formed by the undercut area UC and may be spaced apart from each other in an area overlapping with the contact hole CT. Accordingly, the protective layer 160 may cover an end of the second electrode 230 and stably protect the second electrode 230.

Like the first display unit 11, the second display unit 12 may be disposed with an auxiliary electrode SE, a contact hole CT, and a gap spacer 500.

As described above in FIG. 6, the gap between the first display unit 11 and the second display unit 12 can be stably maintained through the gap spacer 500 of the first display unit 11 and the second display unit 12.

As described above in FIG. 6, an impact applied to the gap spacer 400 may be prevented from affecting the pixel area PA. Specifically, even if a crack occurs in the eighth material layer 580 of the gap spacer 500, the impact applied to the eighth material layer 580 may not be transferred to the protective layer 160. Accordingly, the protective layer 160 may stably protect the light emitting device 200 and prevent moisture from penetrating into the pixel area PA.

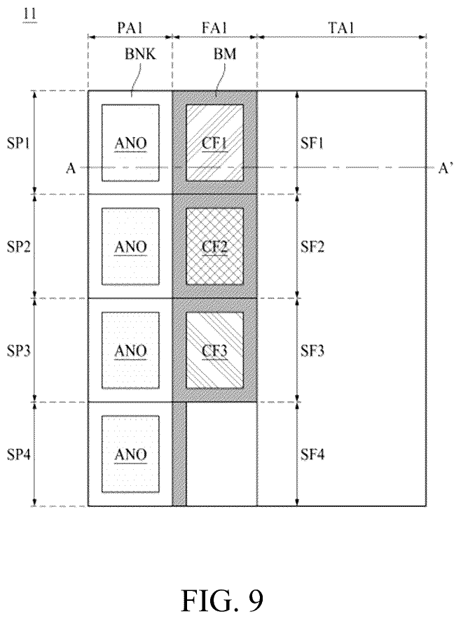

FIG. 9 is a plan view of a double-sided display device 10 according to an embodiment. Specifically, FIG. 9 illustrates a plan view of the first display unit 11.

As described above with reference to FIG. 2, the first display unit 11 may include a first pixel area PA1, a first filter area FA1, and a first transmissive area TA1. The first pixel area PA1, the first filter area FA1, and the first transmissive area TA1 may be disposed sequentially in the row direction.

In this case, the first pixel area PA1 may further include a fourth sub-pixel SP4, and the first filter area FA1 may further include a fourth sub-filter area SF4. In addition, the second display unit 12 may include a fourth sub-pixel SP4 and a fourth sub-filter area SF4 to correspond to the first display unit 11. That is, the fourth sub-pixel SP4 of the first display unit 11 may correspond to the fourth sub-filter area SF4 of the second display unit 12.

The fourth sub-pixel SP4 may be a white sub-pixel. Since the fourth sub-pixel SP4 is a white sub-pixel, the fourth sub-filter area SF4 may not include a color filter. In addition, in the fourth sub-filter area SF4, the black matrix BM may be disposed only in an area adjacent to the fourth sub-pixel SP4. That is, in the fourth sub-filter area SF4, the black matrix BM may not be disposed in an area adjacent to the first transmissive area TA1. Accordingly, an efficiency of the fourth sub-pixel SP4 and an efficiency of the first transmissive area TA1 may be improved.

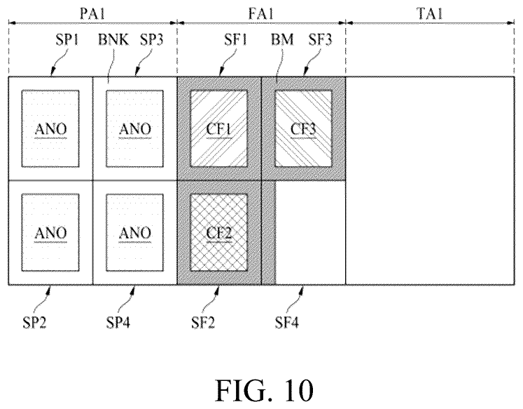

FIG. 10 is a plan view of a double-sided display device 10 according to another embodiment. Specifically, FIG. 10 illustrates a plan view of the first display unit 11.

Referring to FIG. 10, the first display unit 11 may include a first pixel area PA1, a first filter area FA1, and a first transmissive area TA1. In addition, the first pixel area PA1 may include first to fourth sub-pixels SP1 to SP4, and the first filter area FA1 may include first to fourth sub-pixels SF1 to SF4. In this case, the fourth sub-pixel SP4 may be a white sub-pixel.

The first sub-pixel SP1 and the second sub-pixel SP2 may be arranged along the row direction. In addition, the third sub-pixel SP3 and the fourth sub-pixel SP4 may be arranged along the row direction. The first sub-pixel SP1 and the third sub-pixel SP3 may be arranged along the column direction. In addition, the second sub-pixel SP2 and the fourth sub-pixel SP4 may be arranged along the column direction.

Likewise, the first sub-color filter area SF1 and the second sub-color filter area SF2 may be arranged along the row direction. In addition, the third sub-color filter area SF3 and the fourth sub-color filter area SF4 may be arranged along the row direction. The first sub-color filter area SF1 and the third sub-color filter area SF3 may be arranged along the column direction. In addition, the second sub-color filter area SF2 and the fourth sub-color filter area SF4 may be arranged along the column direction.

In addition to an arrangement of the plurality of sub-pixels SP shown in FIGS. 2, 9, and 10, the plurality of sub-pixels SP may be arranged in various manners. In addition, in addition to an arrangement of the plurality of sub-color filter areas SF shown in FIGS. 2, 9, and 10, the plurality of sub-color filter areas SF may be arranged in various manners.

It will be apparent to those skilled in the art that the present disclosure described above is not limited by the above-described embodiments and the accompanying drawings and that various substitutions, modifications and variations can be made in the present disclosure without departing from the technical idea or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A doubled-sided display device comprising:
a first display unit and a second display unit configured on the first display unit;
wherein the first display unit comprises a first pixel area, a first filter area, and a first transmissive area, and wherein the second display unit comprises a second pixel area, a second filter area, and a second transmissive area,
wherein each of the first pixel area and each of the second pixel area comprises a light emitting layer, and wherein each of the first filter area and each of the second filter area comprises a color filter, and
wherein the first pixel area overlaps with the second filter area, the first filter area overlaps with the second pixel area, and the first transmissive area overlaps with the second transmissive area.

2. The doubled-sided display device of claim 1, wherein the first pixel area emits a first light toward the second filter area, and the second pixel area emits a second light toward the first filter area.

3. The doubled-sided display device of claim 1, wherein the first display unit and the second display unit display a same image, or wherein the first display unit and the second display unit display different images.

4. The doubled-sided display device of claim 1, wherein the first display unit further comprises a first pad portion disposed at an edge of the first display unit, and the second display unit further comprises a second pad portion disposed at an edge of the second display unit, and
wherein the first pad portion transmits a signal received from a first printed circuit board to the first pixel area, and the second pad portion transmits a signal received from a second printed circuit board to the second pixel area.

5. The doubled-sided display device of claim 1,
wherein the first display unit comprises:
a substrate comprising the first pixel area and the first filter area; and
a driving thin film transistor disposed on the substrate in the first pixel area, and
wherein the color filter is disposed on the substrate in the first filter area, and the light emitting layer is disposed on the driving thin film transistor and the color filter.

6. The doubled-sided display device of claim 1, further comprising a first insulating layer on a driving thin film transistor and the color filter,
wherein the light emitting layer is disposed on the first insulating layer.

7. The doubled-sided display device of claim 1, further comprising a second insulating layer on a driving thin film transistor,
wherein the color filter is disposed on the second insulating layer, and the light emitting layer is disposed on the color filter.

8. The doubled-sided display device of claim 1, further comprising:
a first auxiliary electrode in a boundary area of the first pixel area and the first filter area;
a first gap spacer on the first auxiliary electrode;
a second auxiliary electrode in a boundary area of the second pixel area and the second filter area; and
a second gap spacer on the second auxiliary electrode,
wherein the first gap spacer and the second gap spacer overlap.

9. The doubled-sided display device of claim 8, wherein the first gap spacer and the second gap spacer are in contact with each other.

10. The doubled-sided display device of claim 8, wherein the first pixel area further comprises a cathode on the light emitting layer, and the cathode is electrically connected to the first auxiliary electrode.

11. The doubled-sided display device of claim 8, further comprising a third insulating layer disposed in the first pixel area and the first filter area and disposed on the first auxiliary electrode,
wherein the third insulating layer comprises a contact hole exposing an upper surface of the first auxiliary electrode, and the first gap spacer is disposed inside the contact hole.

12. The doubled-sided display device of claim 8, wherein the first gap spacer is spaced apart from a third insulating layer disposed in the first pixel area, and wherein the first gap spacer is spaced apart from the third insulating layer disposed in the first filter area.

13. The doubled-sided display device of claim 8, wherein each of the first gap spacer and each of the second gap spacer comprises a same material as the color filter.

14. The doubled-sided display device of claim 8, wherein each of the first gap spacer and each of the second gap spacer comprises a column spacer, and wherein the column spacer is not disposed in the first pixel area, the second pixel area, the first filter area, and the second filter area.
